(19) United States
(12) Patent Application Publication
(10) Pub. No.: US 2026/0282920 A1
(43) Pub. Date: Sep. 17, 2026

(54) PHOTODETECTION DEVICE AND ELECTRONIC APPARATUS

(71) Applicant: SONY SEMICONDUCTOR SOLUTIONS CORPORATION, KANAGAWA (JP)

(72) Inventor: Jiro INOUE, KANAGAWA (JP)

(21) Appl. No.: 19/168,203

(22) PCT Filed: Feb. 21, 2024
(86) PCT No.: PCT/JP2024/006372

§ 371 Date: Sep. 23, 2025

(30) Foreign Application Priority Data
Apr. 4, 2023 (JP) 2023-060791

(51) Int. Cl. H10W 42/00; H10F 39/00

(52) U.S. Cl. CPC H10W 42/121; H10F 39/809; H10F 39/811

(57) ABSTRACT

To further improve reliability of a photodetection device and an electronic apparatus. A photodetection device includes: a semiconductor layer that has a first surface and a second surface located opposite to each other in a thickness direction; a multilayer wiring layer that is provided on the first surface side of the semiconductor layer; a warpage suppression film that is provided on a side opposite to the semiconductor layer side of the multilayer wiring layer; and a recess that overlaps with the warpage suppression film in plan view and extends from the second surface side of the semiconductor layer to the multilayer wiring layer. Then, the warpage suppression film has an opening in an overlapping region overlapping with the recess in plan view.

### TECHNICAL FIELD

The present technology (technology of the present disclosure) relates to a photodetection device and an electronic apparatus, and more particularly relates to a technology effective when applied to a photodetection device including a warpage suppression layer and an electronic apparatus.

### BACKGROUND ART

In a photodetection device such as a solid-state imaging device or a distance measuring device, a stacked type in which semiconductor layers on which elements are formed are stacked in a plurality of stages is known. This stacked type photodetection device can transfer a signal at high speed. Patent Document 1 discloses a solid-state imaging device having a two-stage stacked structure in which two semiconductor layers are stacked. Then, Patent Document 1 also discloses a technology of providing a warpage suppression film (warpage correction layer) for suppressing warpage of a semiconductor substrate including a semiconductor layer and a multilayer wiring layer.

### CITATION LIST

### Patent Document

Patent Document 1: Japanese Patent Application Laid-Open No. 2012-204810

### SUMMARY OF THE INVENTION

### Problems to be Solved by the Invention

Meanwhile, in the stacked-type photodetection device, a multilayer wiring layer is provided on one surface side of a semiconductor layer, and a warpage suppression film is further provided on a side of the multilayer wiring layer opposite to the semiconductor layer side. Then, the multilayer wiring layer provided on the one surface side of the semiconductor layer and an external electrode pad provided on the side opposite to the one surface side of the semiconductor layer are electrically connected through a recess provided in the semiconductor layer.

In the case of such a configuration, stress is locally concentrated around the recess, and deformation may occur in a portion of the multilayer wiring layer overlapping with the recess of the semiconductor layer in plan view. This deformation of the multilayer wiring layer causes warpage or peeling in a wiring and an internal electrode pad of the multilayer wiring layer, and causes deterioration in reliability, and thus there is room for improvement.

An object of the present technology is to provide a technology capable of further improving reliability of a photodetection device and an electronic apparatus.

### Solutions to Problems

(1) A photodetection device according to an aspect of the present technology includes:
a semiconductor layer that has a first surface and a second surface located opposite to each other in a thickness direction;
a multilayer wiring layer that is provided on the first surface side of the semiconductor layer;
a warpage suppression film that is provided on a side opposite to the semiconductor layer side of the multilayer wiring layer; and
a recess that overlaps with the warpage suppression film in plan view and extends from the second surface side of the semiconductor layer to the multilayer wiring layer.

Then, the warpage suppression film has an opening in an overlapping region overlapping with the recess in plan view.

(2) A photodetection device according to another aspect of the present technology includes:
a first semiconductor layer that has a first surface and a second surface located opposite to each other and is provided with a photoelectric conversion unit that photoelectrically converts light incident from the second surface side;
a first multilayer wiring layer that is provided on the first surface side of the first semiconductor layer;
a second semiconductor layer that has a third surface and a fourth surface located opposite to each other and is provided with a transistor;
a second multilayer wiring layer that is provided on the third surface side of the second semiconductor layer so as to overlap with the first multilayer wiring layer;
a warpage suppression film that is provided between the first multilayer wiring layer and the second multilayer wiring layer; and
a recess that overlaps with the warpage suppression film in plan view and extends from the fourth surface side of the second semiconductor layer to the second multilayer wiring layer.

Then, the warpage suppression film has an opening in an overlapping region overlapping with the recess in plan view.

(3) An electronic apparatus according to another aspect of the present technology includes:
the photodetection device;
an optical lens that forms an image of image light from a subject on an imaging surface of the detection device; and
a signal processing circuit that performs signal processing on a signal output from the photodetection device.

### BRIEF DESCRIPTION OF DRAWINGS

FIG. 1 is a chip layout diagram illustrating a configuration example of a solid-state imaging device according to a first embodiment of the present technology.

FIG. 2 is a block diagram illustrating a configuration example of the solid-state imaging device according to the first embodiment of the present technology.

FIG. 3 is an equivalent circuit diagram illustrating a configuration example of a pixel and a pixel circuit according to the first embodiment of the present technology.

FIG. 4 is a longitudinal cross-sectional view schematically illustrating a longitudinal cross-sectional structure taken along line a1-a1 in FIG. 1.

FIG. 5 is a developed view of FIG. 4.

FIG. 6 is an enlarged developed view of a part of FIG. 5.

FIG. 7 is a plan view schematically illustrating a planar pattern in an overlapping region of a warpage suppression film.

FIG. 8 is a longitudinal cross-sectional view schematically illustrating deformation in an overlapping region where a bonding interface between a first laminate and a second laminate overlaps with a recess in a conventional solid-state imaging device.

FIG. 9 is a longitudinal cross-sectional view schematically illustrating deformation in an overlapping region where a bonding interface between a first laminate and a second laminate overlaps with a recess in the solid-state imaging device according to the first embodiment.

FIG. 10 is a plan view schematically illustrating Modification 1-1 of the first embodiment of the present technology.

FIG. 11 is a plan view schematically illustrating Modification 1-2 of the first embodiment of the present technology.

FIG. 12 is a longitudinal cross-sectional view schematically illustrating Modification 1-3 of the first embodiment of the present technology.

FIG. 13 is a longitudinal cross-sectional view schematically illustrating Modification 1-4 of the first embodiment of the present technology.

FIG. 14 is a chip layout diagram illustrating a configuration example of a solid-state imaging device according to a second embodiment of the present technology.

FIG. 15 is a longitudinal cross-sectional view schematically illustrating a longitudinal cross-sectional Structure taken along line a14-a14 in FIG. 14.

FIG. 16 is a diagram illustrating a configuration example of an electronic apparatus according to a third embodiment of the present technology.

### MODE FOR CARRYING OUT THE INVENTION

Hereinafter, embodiments of the present technology will be described in detail with reference to the drawings.

Note that in the illustration of the drawings referred to in the following description, the same or similar portions are denoted by the same or similar reference signs. It should be noted that the drawings are schematic, and a relationship between a thickness and a planar dimension, a ratio of the thicknesses between layers, and the like are different from actual ones. Therefore, specific thicknesses and dimensions should be determined in consideration of the following description.

Furthermore, it goes without saying that dimensional relationships and ratios are partly different between the drawings. Furthermore, the effects described herein are merely illustrative and not limiting, and there may also be other effects.

Furthermore, the following embodiments illustrate device s and methods for embodying the technical idea of the present technology and are not intended to limit the configuration to those described below. That is, various modifications can be made to the technical idea of the present technology within the technical scope described in the claims.

Furthermore, the definitions of directions such as up and down in the following description are merely for convenience of description and are not intended to limit the technical idea of the present technology. For example, it goes without saying that when an object is observed by rotating the object by 90°, the up and down are converted into left and right, and when the object is observed by rotating the object by 180°, the up and down are inverted.

Furthermore, in the following embodiments, in three directions orthogonal to each other in a space, a first direction and a second direction orthogonal to each other in the same plane are defined as an X direction and a Y direction, respectively, and a third direction orthogonal to the first direction and the second direction is defined as a Z direction. Then, in the following embodiments, a thickness direction of a semiconductor layer 30, 70, which will be described later, will be described as the Z direction.

### First Embodiment

In a first embodiment, an example where the present technology is applied to a solid-state imaging device that is a back-illuminated complementary metal-oxide-semiconductor (CMOS) image sensor will be described as a photodetection device.

Furthermore, in the first embodiment, a warpage suppression film (warpage adjusting film) provided between a first laminate (first semiconductor substrate) and a second laminate (second semiconductor substrate) will be described.

### <<Overall Configuration of Solid-State Imaging Device>>

First, an overall configuration of a solid-state imaging device 1A will be described.

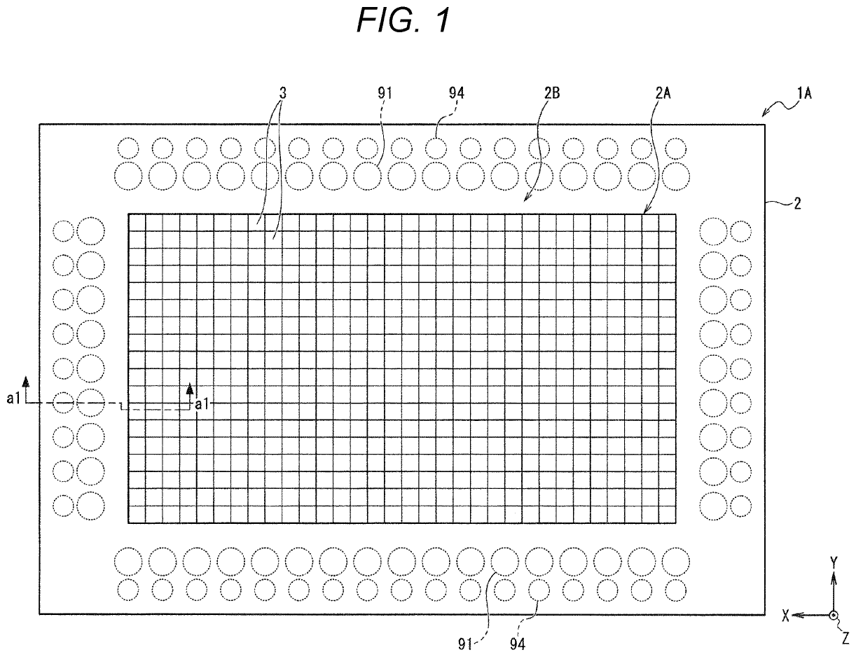

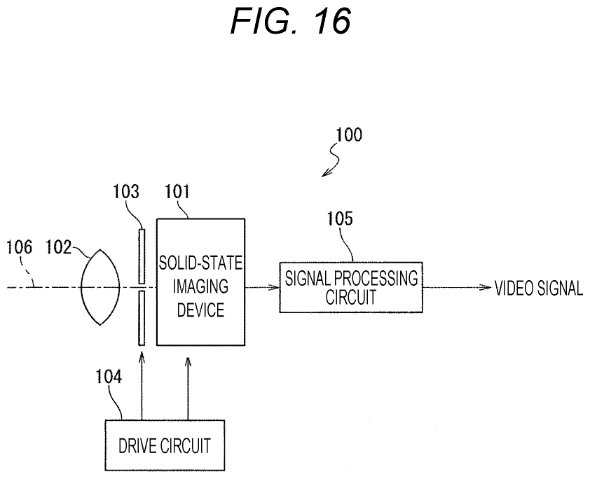

As illustrated in FIG. 1, the solid-state imaging device 1A according to the first embodiment of the present technology mainly includes a semiconductor chip 2 having a rectangular two-dimensional planar shape in plan view. That is, the solid-state imaging device 1A is mounted on the semiconductor chip 2, and the semiconductor chip 2 can be regarded as the solid-state imaging device 1A. As illustrated in FIG. 16, the solid-state imaging device 1A (101) receives image light (incident light 106) from a subject through an optical lens 102, converts an amount of the incident light 106 formed, as an image, on an imaging plane into an electrical signal for each pixel, and outputs the electrical signal as a pixel signal.

As illustrated in FIG. 1, the semiconductor chip 2 on which the solid-state imaging device 1A is mounted includes, in a two-dimensional plane including the X direction and the Y direction orthogonal to each other, a rectangular sensor pixel array unit 2A provided in a central portion thereof and a peripheral portion 2B provided outside the sensor pixel array unit 2A in such a way as to surround the sensor pixel array unit 2A. The semiconductor chip 2 is formed in a manufacturing process by dicing a semiconductor wafer including first and second semiconductor layers 30 and 70, which will be described later, into small pieces for each chip formation region. The configuration of the solid-state imaging device 1A, which will be described below, therefore, is substantially similar to that before the semiconductor wafer is cut into small pieces. That is, the present technology is applicable to both a semiconductor chip and a semiconductor wafer.

The sensor pixel array unit 2A is, for example, a light receiving surface that receives light condensed by the optical lens (optical system) 102 illustrated in FIG. 16. Then, a plurality of sensor pixels (pixels) 3 is arranged in the sensor pixel array unit 2A in a matrix in the two-dimensional plane including the X direction and the Y direction. In other words, the sensor pixels 3 are repeatedly arranged in the X direction and the Y direction orthogonal to each other in the two-dimensional plane.

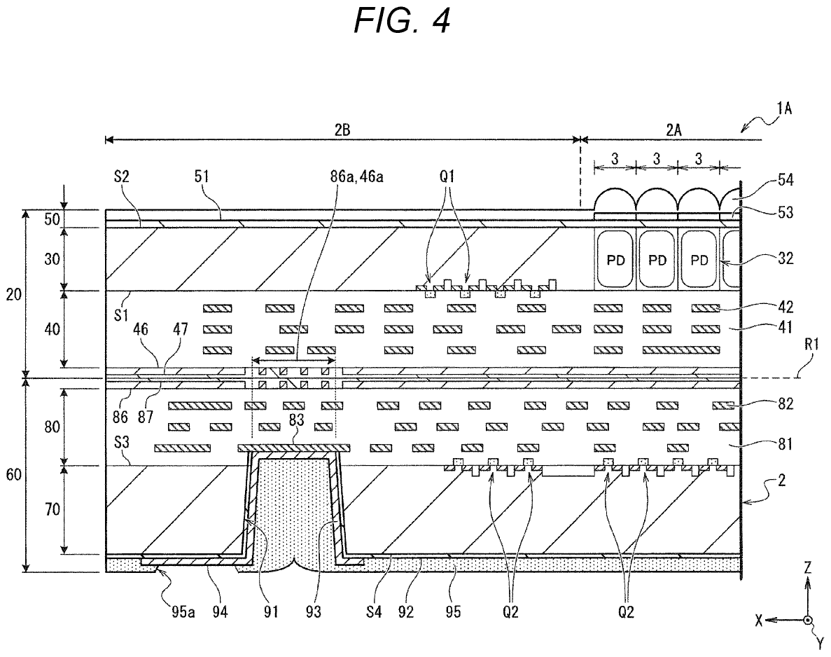

As illustrated in FIG. 1, a plurality of external electrode pads 94 is arranged in the peripheral portion 2B. As illustrated in FIG. 4, the plurality of external electrode pads 94 is provided on a side of the semiconductor chip 2 opposite to the sensor pixel array unit 2A side. As illustrated in FIG. 1, each bonding pad of the plurality of external electrode pads 94 is arranged along each of four sides of the two-dimensional plane of the semiconductor chip 2, for example. Each of the plurality of external electrode pads 94 functions as an input/output terminal for electrically connecting the semiconductor chip 2 to an external device.

### <Logic Circuit>

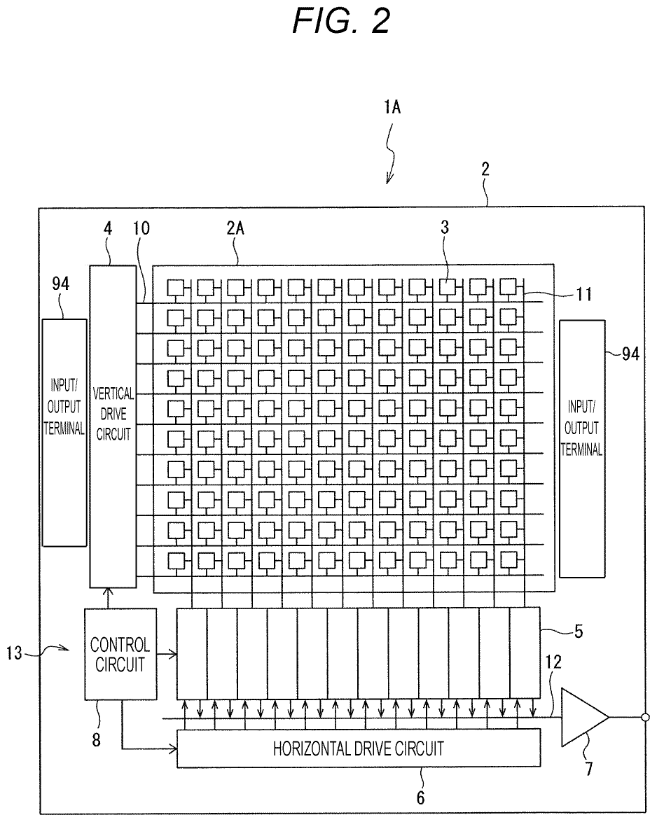

The semiconductor chip 2 includes a logic circuit 13 illustrated in FIG. 2. As illustrated in FIG. 2, the logic circuit 13 includes a vertical drive circuit 4, column signal processing circuits 5, a horizontal drive circuit 6, an output circuit 7, a control circuit 8, and the like. The logic circuit 13 includes, for example, a complementary MOS (CMOS) circuit including an n-channel metal-oxide-semiconductor field-effect transistor (MOSFET) and a p-channel MOSFET as field-effect transistors.

The vertical drive circuit 4 illustrated in FIG. 2 includes a shift register, for example. The vertical drive circuit 4 sequentially selects a desired pixel drive line 10, supplies a pulse for driving the sensor pixels 3 to the selected pixel drive line 10, and drives the respective sensor pixels 3 row by row. That is, the vertical drive circuit 4 selectively scans each of the sensor pixels 3 in the sensor pixel array unit 2A sequentially in a vertical direction on a row-by-row basis, and supplies a pixel signal from each of the sensor pixels 3 based on a signal charge generated in accordance with the amount of received light by a photoelectric conversion unit (photoelectric conversion element) of the sensor pixel 3 to the column signal processing circuit 5 through a vertical signal line 11.

The column signal processing circuit 5 illustrated in FIG. 2 is arranged, for example, for each column of the sensor pixels 3, and performs signal processing such as noise removal for each pixel column on signals output from the sensor pixels 3 of one row. For example, each column signal processing circuit 5 performs signal processing such as correlated double sampling (CDS) for removing pixel-specific fixed pattern noise, and analog-to-digital (AD) conversion.

The horizontal drive circuit 6 illustrated in FIG. 2 includes, for example, a shift register. The horizontal drive circuit 6 sequentially outputs horizontal scanning pulses to the column signal processing circuits 5 to sequentially select each of the column signal processing circuits 5, and causes each of the column signal processing circuits 5 to output a pixel signal subjected to signal processing to the horizontal signal line 12.

The output circuit 7 illustrated in FIG. 2 performs signal processing on the pixel signals sequentially supplied from each of the individual column signal processing circuits 5 through the horizontal signal line 12, and outputs a processed signal. As the signal processing, buffering, black level adjustment, column variation correction, various kinds of digital signal processing, and the like can be used, for example.

The control circuit 8 illustrated in FIG. 2 generates a clock signal and a control signal as a reference for operations of the vertical drive circuit 4, the column signal processing circuit 5, the horizontal drive circuit 6, and the like, on the basis of a vertical synchronization signal, a horizontal synchronization signal, and a master clock signal. Then, the control circuit 8 outputs the generated clock signal and control signal to the vertical drive circuit 4, the column signal processing circuits 5, the horizontal drive circuit 6, and the like.

### <Circuit Configuration of Sensor Pixel>

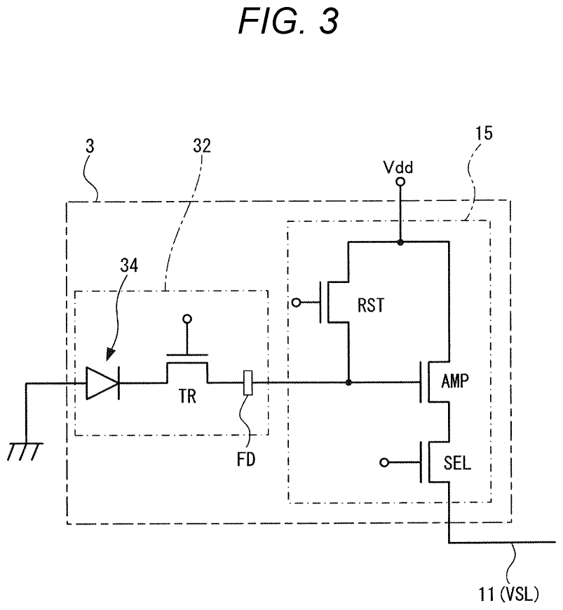

As illustrated in FIG. 3, each sensor pixel 3 of the plurality of sensor pixels 3 includes a photoelectric conversion region 32 and a pixel circuit (readout circuit) 15. The photoelectric conversion region 32 includes a photoelectric conversion unit 34, a transfer transistor TR as a pixel transistor, and a floating diffusion region FD as a charge holding portion. The pixel circuit 15 is electrically connected to the floating diffusion region FD of the photoelectric conversion region 32.

The first embodiment has, but is not limited to, a circuit configuration in which one pixel circuit 15 is allocated to one sensor pixel 3 as an example. For example, a circuit configuration in which one pixel circuit 15 is shared by a plurality of sensor pixels 3 may be adopted. Specifically, a circuit configuration may be adopted in which one pixel circuit 15 is shared by one sensor pixel group (photoelectric conversion group) in which four sensor pixels 3 arranged in a two-by-two layout are set as one unit, that is, two sensor pixels 3 are arranged in the X direction and two sensor pixels 3 are arranged in the Y direction. Furthermore, a circuit configuration may be adopted in which one pixel circuit 15 is shared by one sensor pixel group (photoelectric conversion group) in which two sensor pixels 3 are set as one unit. Furthermore, a circuit configuration may be adopted in which one pixel circuit 15 is shared by one sensor pixel group (photoelectric conversion group) in which four or more sensor pixels 3 are set as one unit.

The photoelectric conversion unit 34 illustrated in FIG. 3 includes, for example, a p-n junction type photodiode (PD), and generates a signal charge according to the amount of light received. The photoelectric conversion unit 34 has a cathode side electrically connected to a source region of the transfer transistor TR and an anode side electrically connected to a reference potential line (for example, ground).

The transfer transistor TR illustrated in FIG. 3 transfers the signal charge generated by the photoelectric conversion unit 34 as a result of photoelectric conversion to the floating diffusion region FD. A source region of the transfer transistor RT is electrically connected to the cathode side of the photoelectric conversion unit 34, and the drain region of the transfer transistor TR is electrically connected to the floating diffusion region FD. Then, the gate electrode of the transfer transistor TR is electrically connected to a transfer transistor drive line among the pixel drive lines 10 illustrated in FIG. 2.

The floating diffusion region FD illustrated in FIG. 3 temporarily holds (accumulates) signal charges transferred from the photoelectric conversion unit 24 via the transfer transistor TR.

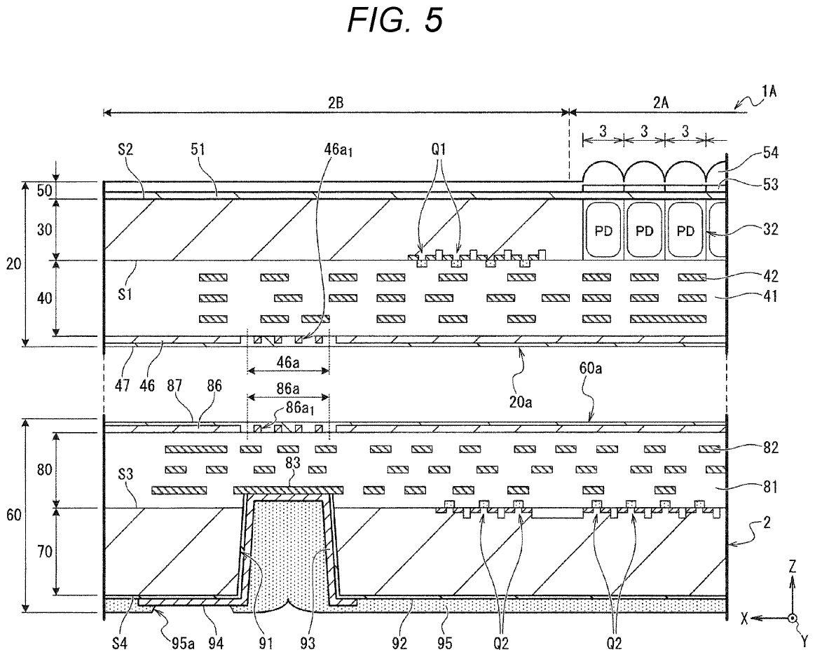

The photoelectric conversion region 32 including the photoelectric conversion unit 34, the transfer transistor TR, and the floating diffusion region FD is mounted on the first semiconductor layer 30 illustrated in FIGS. 4 and 5 for each sensor pixel 3.

The pixel circuit 15 illustrated in FIG. 3 reads signal charges held in the floating diffusion region FD, and outputs pixel signals based on the read signal charges. Although not limited thereto, the pixel circuit 15 includes, for example, an amplification transistor AMP, a selection transistor SEL, and a reset transistor RST as a pixel transistor Q. Each of these pixel transistors (AMP, SEL, RST) and the above-described transfer transistor TR includes, as a field-effect transistor, a MOSFET having, for example, a gate insulating film formed by a silicon oxide (SiO₂) film, a gate electrode, and a pair of main electrode regions that functions as a source region and a drain region. Furthermore, these transistors may each be a metal-insulator-semiconductor FET (MISFET) having, as a gate insulating film, a silicon nitride (Si₃N₄) film or a multilayer film such as a silicon nitride film and a silicon oxide film.

The amplification transistor AMP illustrated in FIG. 3 has a source region electrically connected to a drain region of the selection transistor SEL and a drain region electrically connected to a power supply line Vdd and a drain region of the reset transistor RST. Then, a gate electrode of the amplification transistor AMP is electrically connected to the floating diffusion region FD and a source region of the reset transistor RST.

The selection transistor SEL illustrated in FIG. 3 has a source electrically connected to the vertical signal line 11 (VSL) and the drain region electrically connected to the source region of the amplification transistor AMP. Then, a gate electrode of the selection transistor SEL is electrically connected to a selection transistor drive line among pixel drive lines 10 illustrated in FIG. 2.

The reset transistor RST illustrated in FIG. 3 has the source region electrically connected to the floating diffusion region FD and the gate electrode of the amplification transistor AMP and the drain region electrically connected to the power supply line Vdd and the drain region of the amplification transistor AMP. Then, a gate electrode of the reset transistor RST is electrically connected to a reset transistor drive line among the pixel drive lines 10 illustrated in FIG. 2.

When the transfer transistor TRG is turned on, the transfer transistor TR illustrated in FIG. 3 transfers the signal charge generated by the photoelectric conversion unit 24 to the floating diffusion region FD.

When the reset transistor RST is turned on, the reset transistor RST illustrated in FIG. 3 resets a potential (signal charge) of the floating diffusion region FD to a potential of the power supply line Vdd. The selection transistor SEL controls the output timing of the pixel signal from the pixel circuit 15.

The amplification transistor AMP illustrated in FIG. 3 generates a signal of a voltage corresponding to a level of the signal charge held in the floating diffusion region FD as a pixel signal. The amplification transistor AMP functions as a source follower amplifier, and outputs the pixel signal indicating the voltage corresponding to the level of the signal charge generated by the photoelectric conversion unit 24. When the selection transistor SEL is turned on, the amplification transistor AMP amplifies the potential of the floating diffusion region FD, and outputs a voltage corresponding to the potential to the column signal processing circuit 5 via the vertical signal line 11 (VSL).

Here, referring to FIG. 3, during the operation of the solid-state imaging device 1A according to the first embodiment, the signal charge generated by the photoelectric conversion unit 34 of the sensor pixel 3 is held (accumulated) in the floating diffusion region FD via the transfer transistor TR of the sensor pixel 3. Then, the signal charge held in the floating diffusion region FD is read by the pixel circuit 15 and applied to the gate electrode of the amplification transistor AMP of the pixel circuit 15. A horizontal selection control signal is supplied from the vertical shift register to the gate electrode of the selection transistor SEL of the pixel circuit 15. Then, by setting the selection control signal to a high (H) level, the selection transistor SEL is conducted, and a current corresponding to the potential of the floating diffusion region FD amplified by the amplification transistor AMP flows through the vertical signal line 11. Furthermore, by setting a reset control signal applied to the gate electrode of the reset transistor RST of the pixel circuit 15 to the high (H) level, the reset transistor RST is conducted, and the signal charge accumulated in the floating diffusion region FD is reset.

### <Other Pixel Circuits>

Note that the selection transistor SEL may be omitted as necessary. Note that in a case where the selection transistor SEL is omitted, the source region of the amplification transistor AMP is electrically connected to the vertical signal line 11 (VSL).

Furthermore, a switching transistor may be provided between the reset transistor RST and the floating diffusion region FD and the gate electrode of the amplification transistor AMP. The switching transistor controls charge holding by the floating diffusion region FD, and adjusts an amplification factor of a voltage according to the potential amplified by the amplification transistor AMP.

Furthermore, the switching transistor is used to switch conversion efficiency. In general, a pixel signal is small at a time of capture of an image in a dark place. Since Q=CV, If the FD capacitance C (floating diffusion capacitance C) of the charge holding portion (floating diffusion region FD) is high when charge-voltage conversion is performed, a voltage V when converted into a voltage by the amplification transistor AMP becomes low. On the other hand, since a pixel signal becomes large in a bright place, the charge holding portion cannot fully receive the charge of the photoelectric conversion unit 24 (photodiode PD) unless the FD capacitance C of the charge holding portion is high. Moreover, the FD capacitance C of the charge holding portion needs to be high so that the voltage V obtained by the amplification transistor AMP as a result of the conversion into a voltage does not become too high (in other words, becomes low). For these reasons, when the switching transistor is turned on, the gate capacitance corresponding to the switching transistor increases, and thus the entire FD capacitance C increases. On the other hand, when the switching transistor is turned off, the entire FD capacitance C decreases. In this manner, by performing ON/OFF switching of the switching transistor, the FD capacitance C can be made variable, and the conversion efficiency can be switched.

### <<Specific Configuration of Solid-State Imaging Device>>

Next, a specific configuration of the solid-state imaging device 1A will be described with reference to FIGS. 4 to 7.

As illustrated in FIGS. 4 and 5, the solid-state imaging device 1A (semiconductor chip 2) includes a first laminate (first semiconductor substrate) 20 and a second laminate (second semiconductor substrate) 60. Then, the first laminate 20 and the second laminate 60 are bonded in a state where bonding surfaces 20a and 60a thereof face each other. The sensor pixel array unit 2A, the control circuit 8, the pixel circuit 15, and the like are mounted on the first laminate 20. The logic circuit 13 including the vertical drive circuit 4, the column signal processing circuit 5, the horizontal drive circuit 6, the output circuit 7, and the like is mounted on the second laminate 60.

### <First Laminate>

As illustrated in FIGS. 4 and 5, the first laminate 20 includes a first semiconductor layer 30 having a first surface S1 and a second surface S2 located on opposite sides in the thickness direction (Z direction), a first multilayer wiring layer 40 provided on the first surface S1 side of the first semiconductor layer 30, and a light condensing layer 50 provided on the second surface S2 side of the first semiconductor layer 30.

Furthermore, the first laminate 20 includes a warpage suppression film 46 and a bonding layer 47 sequentially stacked from the first multilayer wiring layer 40 side on the side of the first multilayer wiring layer 40 opposite to the first semiconductor layer 30 side.

Here, the first surface S1 of the first semiconductor layer 30 may also be referred to as a main surface or an element formation surface, and the second surface S2 may also be referred to as a back surface. Then, as will be described in detail later, the solid-state imaging device 1A according to the first embodiment photoelectrically converts incident light incident from the second surface S2 side of the first semiconductor layer 30 by the photoelectric conversion unit 34 (photodiode PD) provided in the photoelectric conversion region 32 of the first semiconductor layer 30.

Therefore, in the first embodiment, the second surface S2 of the first semiconductor layer 30 may also be referred to as a light incident surface.

### <Second Laminate>

The second laminate 60 includes a second semiconductor layer 70 having a third surface S3 and a fourth surface S4 located on opposite sides in the thickness direction (Z direction), and a second multilayer wiring layer 80 provided on the third surface S3 side of the second semiconductor layer 70.

Furthermore, the second laminate 60 includes a recess 91 extending from the third surface S3 side of the second semiconductor layer 70 to the second multilayer wiring layer 80, an isolation insulating film 92 provided along the inner wall of the recess 91, and a contact electrode 93 provided along the inner wall of the recess 91 via the isolation insulating film 92 and electrically connected to the second multilayer wiring layer 80.

Furthermore, the second laminate 60 includes an external electrode pad 94 provided on the fourth surface S4 side of the second semiconductor layer 70 and electrically connected to the contact electrode 93, and a solder resist film 95 provided in the recess 91 via the contact electrode 93.

Furthermore, the second laminate 60 includes a warpage suppression film 86 and a bonding layer 87 sequentially stacked from the second multilayer wiring layer 80 side on the side of the second multilayer wiring layer 80 opposite to the second semiconductor layer 70 side.

Here, the third surface S3 of the second semiconductor layer 70 may also be referred to as a main surface or an element formation surface, and the fourth surface S4 may also be referred to as a back surface.

### <Light Condensing Layer>

As illustrated in FIGS. 4 and 5, the light condensing layer 50 is provided on the second surface S2 side of the first semiconductor layer 30. Then, the light condensing layer 50 has a stacked structure in which, for example, a planarization film 51, an optical filter 53, and an on-chip lens 54 are stacked in this order from the second surface S2 side of the first semiconductor layer 30, although not limited thereto.

The planarization film 51 is provided on the second surface S2 side of the semiconductor layer 30 in such a way as to to cover the second surface portion S2 of the semiconductor layer 30, and planarizes the second surface S2 side of the semiconductor layer 30.

The optical filter 53 and a microlens 54 are provided for each sensor pixel 3. The optical filter 53 color-separates incident light incident from a light incident surface side (second surface S2 side) of the semiconductor chip 2. The microlens 54 condenses the irradiation light and allows the condensed light to efficiently enter the sensor pixel 3 (photoelectric conversion region 32).

### <First Semiconductor Layer>

As illustrated in FIGS. 4 and 5, the first semiconductor layer 30 is provided on the third surface S3 side of the second semiconductor layer 70 via the first multilayer wiring layer 40 and the second multilayer wiring layer 80. The first semiconductor layer 30 includes, for example, a p-type single crystal silicon substrate. The photoelectric conversion region 32 is provided for each sensor pixel 3 in a region of the first semiconductor layer 30 overlapping with the sensor pixel array unit 2A in plan view. Although not illustrated, the photoelectric conversion region 32 is partitioned by an isolation region provided in the first semiconductor layer 30. Note that the number of sensor pixels 3 is not limited to that in FIGS. 4 and 5.

Although not illustrated, the photoelectric conversion region 32 includes, for example, a p-type well region and an n-type semiconductor region (photoelectric conversion unit) embedded in the well region. The photoelectric conversion element PD illustrated in FIG. 3 is configured in a photoelectric conversion region 32 including the well region and the photoelectric conversion unit of the first semiconductor layer 30. Furthermore, the photoelectric conversion region 32 is provided with, for example, the floating diffusion region (charge holding portion) FD including an n-type semiconductor region, and the transfer transistor TR, although not limited thereto.

As illustrated in FIGS. 4 and 5, a plurality of transistors Q1 is provided on the first surface S1 of the first semiconductor layer 30. The transistor Q1 is provided in the semiconductor layer 30 immediately below the peripheral portion 2B in plan view. The transistor Q1 is, for example, a transistor constituting the control circuit 8 illustrated in FIG. 2. As the transistor Q1, for example, a metal oxide semiconductor field-effect transistor (MOS transistor) is used. FIGS. 4 and 5 illustrate four transistors Q1 as a representative of the plurality of transistors.

### <First Multilayer Wiring Layer>

As illustrated in FIGS. 4 and 5, the first multilayer wiring layer 40 is stacked on the first surface S1 side of the first semiconductor layer 30. The first multilayer wiring layer 40 has a multilayer wiring structure in which a plurality of stages of wiring layers 42 are stacked with an interlayer insulating film 41 interposed therebetween. In FIGS. 4 and 5, although not limited thereto, for example, a three-layer wiring structure in which the wiring layers 42 are stacked in three stages is illustrated.

The interlayer insulating film 41 is, for example, a silicon oxide film. The wiring layer 42 is formed by, for example, a copper (Cu) film or a Cu alloy film containing Cu as a main component, or an aluminum (Al) film or an Al alloy film containing Al as a main component.

### <Second Semiconductor Layer>

As illustrated in FIGS. 4 and 5, the second semiconductor layer 70 is provided on the first surface S1 side of the first semiconductor layer 30 via the second multilayer wiring layer 80 and the first multilayer wiring layer 40. The second semiconductor layer 70 includes, for example, a p-type single crystal silicon substrate.

As illustrated in FIGS. 4 and 5, a plurality of transistors Q2 is provided on the third surface S3 of the semiconductor layer 70. The transistor Q2 is, for example, a pixel transistor constituting the pixel circuit (readout circuit) 15 illustrated in FIG. 3 or a transistor constituting the logic circuit 13 illustrated in FIG. 2. As the transistor Q2, for example, a MOS transistor is used. FIGS. 4 and 5 illustrate seven transistors Q2 as a representative of the plurality of transistors.

### <Second Multilayer Wiring Layer>

As illustrated in FIGS. 4 and 5, the second multilayer wiring layer 80 is stacked on the third surface S3 side of the second semiconductor layer 70. The second multilayer wiring layer 80 has a multilayer wiring structure in which a plurality of stages of wiring layers 82 are stacked with an interlayer insulating film 81 interposed therebetween. In FIGS. 4 and 5, although not limited thereto, for example, a three-layer wiring structure in which the wiring layers 82 are stacked in three stages is illustrated.

As illustrated in FIGS. 4 and 5, the second multilayer wiring layer 80 includes an internal electrode pad 83. The internal electrode pad 83 is provided on the wiring layer 82, which is the first layer when counted from the second semiconductor layer 70 side of the second multilayer wiring layer 80.

The interlayer insulating film 81 is, for example, a silicon oxide film. The wiring layer 82 is formed by, for example, a copper (Cu) film, a Cu alloy film containing Cu as a main component, an aluminum (Al) film, or an Al alloy film containing Al as a main component.

### <Recess, Isolation Insulating Film>

As illustrated in FIGS. 4 and 5, the recess 91 is provided at a position overlapping with the internal electrode pad 83 of the second multilayer wiring layer 80 in plan view. Then, the recess 91 extends from the third surface S3 side of the second semiconductor layer 70 to the second multilayer wiring layer 80 and reaches the internal electrode pad 83. The recess 91 can be formed by selectively etching the second semiconductor layer 70 and the second multilayer wiring layer 80 by using well-known photolithography technology and anisotropic dry etching technology.

As illustrated in FIG. 1, although not limited thereto, for example, a plurality of recesses 91 is provided in the peripheral portion 2B.

As illustrated in FIGS. 4 and 5, the isolation insulating film 92 is provided along the side surface of the inner wall of the recess 91 and is also provided on the fourth surface S4 side of the second semiconductor layer 70. That is, the isolation insulating film 92 is provided over the side surface of the inner wall of the recess 91 and the fourth surface S4 of the second semiconductor layer 70. The isolation insulating film 92 is, for example, a silicon oxide film.

### <Contact Electrode, External Electrode Pad>

As illustrated in FIGS. 4 and 5, the contact electrode 93 is provided along the inner wall of the recess 91 via the isolation insulating film 92, and is provided along the internal electrode pad 83 located at the bottom of the recess 91. Then, the contact electrode 93 is electrically and mechanically connected to the internal electrode pad 83. Then, the contact electrode 93 is electrically insulated and separated from the second semiconductor layer 70 via the isolation insulating film 92.

As illustrated in FIGS. 4 and 5, the external electrode pad 94 is provided on the fourth surface S4 side of the second semiconductor layer 70 via the isolation insulating film 92. The external electrode pad 94 is formed integrally with the contact electrode 93, and is electrically connected to the contact electrode 93. That is, the external electrode pad 94 is electrically connected to the internal electrode pad 83 of the second multilayer wiring layer 80 through the recess 91. Then, the recess 91 is a through hole for electrically connecting the internal electrode pad 83 on the third surface S3 side of the second semiconductor layer 70 and the external electrode pad 94 on the fourth surface S4 side of the second semiconductor layer 70, and penetrates the second semiconductor layer 70 along the thickness direction (Z direction) of the second semiconductor layer 70. Then, the external electrode pad 94 is electrically insulated and separated from the second semiconductor layer 70 via the isolation insulating film 92.

The contact electrode 93 and the external electrode pad 94 can be formed, for example, by forming a conductive film on the fourth surface S4 side of the second semiconductor layer 70 and inside the recess 91 with a film thickness along the inner wall of the recess 91, and thereafter, patterning the conductive film by a known photolithography technology and an anisotropic dry etching technology. As the conductive film, for example, a stacked film of a titanium (Ti) film as a barrier film and a copper (Cu) film as a seed film can be used.

As illustrated in FIG. 1, although not limited thereto, for example, a plurality of external electrode pads 94 is provided in the peripheral portion 2B of the semiconductor chip 2.

### <Solder Resist>

As illustrated in FIGS. 4 and 5, the solder resist film 95 is provided inside the recess 91 so as to cover the contact electrode 93, and is provided so as to cover the fourth surface S4 of the second semiconductor layer 70. That is, the solder resist film 95 is provided over the inside of the recess 91 and the fourth surface S4 of the second semiconductor layer 70.

The solder resist film 95 is provided mainly for the purpose of protecting the contact electrode 93 and wiring (not illustrated) provided on the fourth surface S4 side of the second semiconductor layer 70. Then, the solder resist film 95 is provided with an opening 95a through which the external electrode pad 94 is exposed.

A connection member such as a solder bump or a bonding wire is connected to the external electrode pad 94 through the opening 95a of the solder resist film 95.

### <Bonding Layer>

As illustrated in FIG. 5, the bonding layer 47 on the first laminate 20 side is provided on the bonding surface side of the first multilayer wiring layer 40 on the side opposite to the first semiconductor layer 30 side, so as to cover the warpage suppression film 46. The bonding layer 46 is provided over the sensor pixel array unit 2A and the peripheral portion 2B of the semiconductor chip 2, and is provided over a wide range so as to cover the entire region of the first multilayer wiring layer 40 in plan view.

As illustrated in FIG. 5, the bonding layer 87 on the second laminate 20 side is provided on the bonding surface side of the second multilayer wiring layer 80 on the side opposite to the second semiconductor layer 70 side, so as to cover the warpage suppression film 86. The bonding layer 87 is provided over the sensor pixel array unit 2A and the peripheral portion 2B of the semiconductor chip 2, and is provided over a wide range so as to cover the entire region of the second multilayer wiring layer 80 in plan view.

The surface of the bonding layer 47 functions as the bonding surface 20a of the first laminate 20. On the other hand, the bonding layer 87 functions as the bonding surface 60a of the second laminate 60. Then, the bonding layer 47 of the first laminate 20 and the bonding layer 87 of the second laminate 60 are bonded. Then, by bonding the bonding layer 47 of the first laminate 20 and the bonding layer 87 of the second laminate 60, the first laminate 20 and the second laminate 60 are bonded side by side in each thickness direction (Z direction).

### <Plasma Bonding Method>

Bonding between the bonding layer 47 of the first laminate 20 and the bonding layer 87 of the second laminate 60 can be performed by, for example, a plasma bonding method.

In the plasma bonding method, a silanol group is formed by applying plasma irradiation to a silicon oxide layer as a bonding layer. Then, the surfaces having silanol groups formed thereon are brought to face each other, and the laminates are pressed against each other to be bonded by van der Waals forces. Thereafter, in order to further increase an adhesive force at the bonding interface, for example, a heat treatment at 400° C./60 min is applied to cause the silanol groups to undergo a dehydration condensation reaction. By performing such molecular level control on the bonding layer of the laminate, the laminates can be bonded to each other. The bonding between the bonding layer 47 of the first laminate 20 and the bonding layer 87 of the second laminate 60 is performed in a wafer state.

### <Warpage Suppression Film>

As illustrated in FIG. 5, the warpage suppression film 46 is provided on the side of the first multilayer wiring layer 40 opposite to the first semiconductor layer 30 side, and is covered with the bonding layer 47. The warpage suppression film 46 is provided over the sensor pixel array unit 2A and the peripheral portion 2B of the semiconductor chip 2, and is provided over a wide range so as to cover the entire region of the first multilayer wiring layer 40 in plan view.

The warpage suppression film 46 is for suppressing warpage of the first laminate 20 in which the first semiconductor layer 30 and the first multilayer wiring layer 40 having different thermal expansion coefficients are stacked, and includes a layer having an internal stress opposite to that of the warpage of the first laminate 20. As the warpage suppression film 46, for example, a material that can be formed by a plasma CVD method such as SiN, SiO2, SiOC, SiC, SiCN, FSG, or FTEOS, or a material that can be formed by a coating method such as an inductive material or SOG can be used. In particular, in the film formed by using the plasma CVD method, the internal stress can be controlled by changing conditions such as the pressure in the chamber of the CVD apparatus and RF power. Therefore, it is preferable to use the material film formed by using the plasma CVD method as the warpage suppression film 46. In the first embodiment, for example, a silicon nitride (SiN) film is used as the warpage suppression film 46.

As illustrated in FIG. 5, the warpage suppression film 86 is provided on the side of the second multilayer wiring layer 80 opposite to the second semiconductor layer 70 side, and is covered with the bonding layer 87. The warpage suppression film 86 is provided over the pixel array unit 2A and the peripheral portion 2B of the semiconductor chip 2, and is provided over a wide range so as to cover the entire region of the second multilayer wiring layer 80 in plan view.

The warpage suppression film 86 is for suppressing warpage of the second laminate 60 in which the second semiconductor layer 70 and the second multilayer wiring layer 80 having different thermal expansion coefficients are stacked, and includes a layer having an internal stress opposite to the warpage of the second laminate 60. The warpage suppression film 46 can have a configuration similar to that of the warpage suppression film 46 that suppresses the warpage of the first laminate 20 described above. In the first embodiment, for example, a silicon nitride (SiN) film is used as the warpage suppression film 86.

As illustrated in FIG. 5, each of the warpage suppression films 86 and 46 is provided between the second multilayer wiring layer 80 and the first multilayer wiring layer 40.

That is, the solid-state imaging device 1A according to the first embodiment includes the second semiconductor layer 70, the second multilayer wiring layer 80 which is provided on the third surface S3 side of the second semiconductor layer 70, the warpage suppression film 86 which is provided on the side of the second multilayer wiring layer 80 opposite to the second semiconductor layer 70 side, and the recess 91 which overlaps with the warpage suppression film 86 in plan view and extends from the fourth surface S4 side of the second semiconductor layer 70 to the second multilayer wiring layer.

### <Overlapping Region of Warpage Suppression Film>

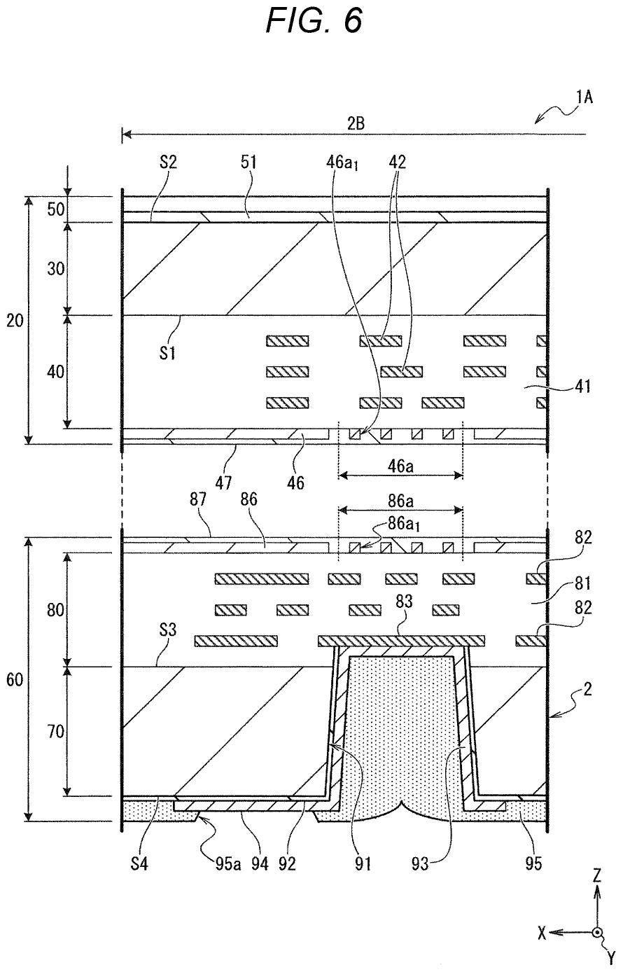

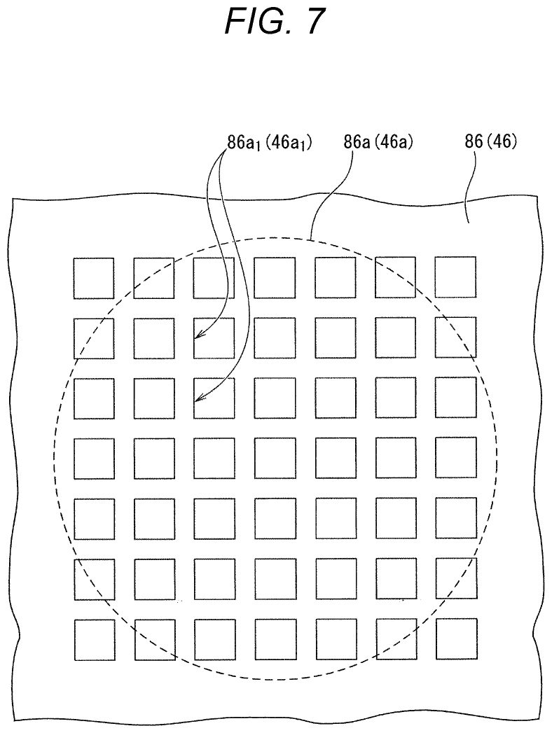

As illustrated in FIGS. 6 and 7, the warpage Suppression film 86 has an opening 86a₁ in an overlapping region 86a overlapping with the recess 91 in plan view. The openings 86a₁ are, but not limited to, interspersed, for example. Then, the overlapping region 86a of the warpage suppression film 86 is a lattice-shaped planar pattern including the opening 86a₁.

As illustrated in FIG. 6, the opening 86a₁ penetrates the warpage suppression film 86, for example. Then, as illustrated in FIG. 7, the planar shape of the opening 46a₁ is, for example, a rectangular shape.

As illustrated in FIG. 6, the warpage suppression film 46 also has the opening 46a₁ in an overlapping region 46a overlapping with the recess 91 in plan view, similarly to the warpage suppression film 86 described above. Similarly to the openings 86a₁ of the warpage Suppression film 86 described above, the openings 46a₁ are also interspersed, for example. Then, the overlapping region 46a of the warpage suppression film 46 is also a lattice-shaped planar pattern including the opening 46a₁. Then, similarly to the above-described opening 86a₁, the opening 46a₁ of the warpage suppression film 46 also penetrates the warpage suppression film 46, for example, and the planar shape of the opening 46a₁ is, for example, a rectangular shape.

### <<Main Effects of First Embodiment>>

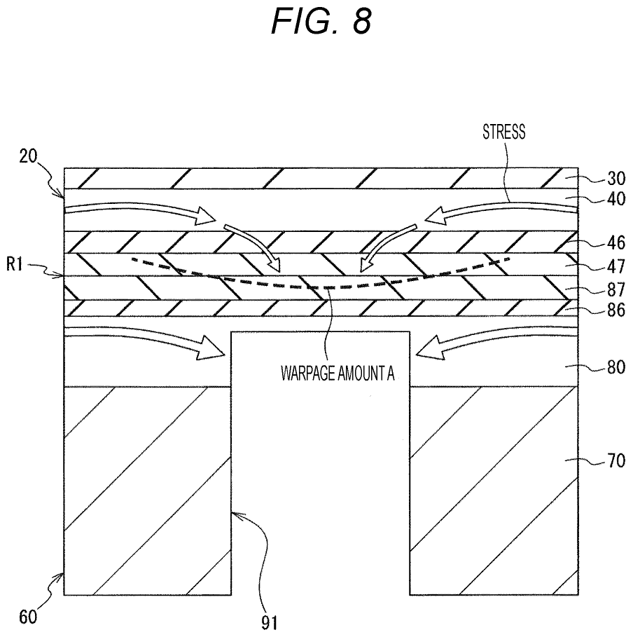

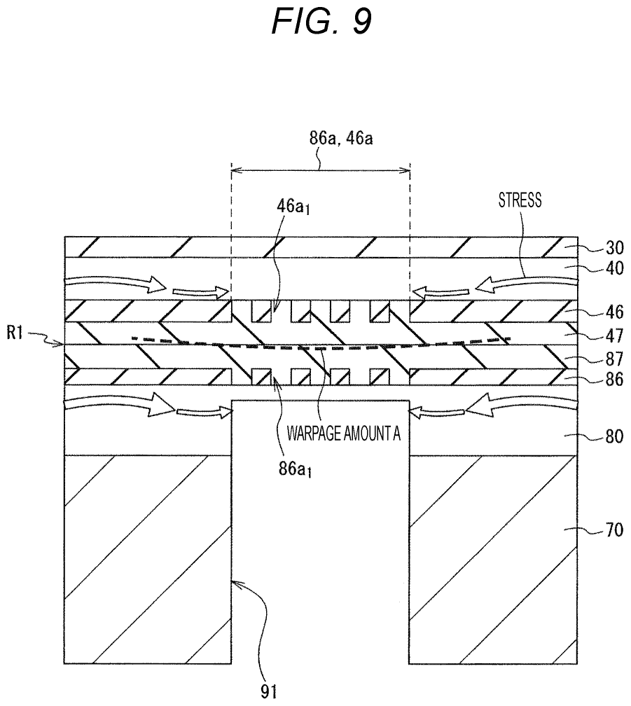

Next, main effects of the first embodiment will be described with reference to FIGS. 8 and 9.

FIG. 8 is a longitudinal cross-sectional view schematically illustrating deformation in an overlapping region where a bonding interface R1 between the first laminate 20 and the second laminate 60 overlaps with the recess 91 in a conventional solid-state imaging device.

FIG. 9 is a longitudinal cross-sectional view schematically illustrating deformation in an overlapping region where a bonding interface between the first laminate 20 and the second laminate 60 overlaps with the recess 91 in the solid-state imaging device 1A according to the first embodiment.

As illustrated in FIG. 8, in the conventional solid-state imaging device, the overlapping regions 86a and 46a of the warpage suppression films 86 and 46 overlapping with the recess 91 of the second semiconductor layer 70 in plan view are in a solid film state. That is, the entire recess 91 is covered with the warpage suppression films 86 and 46 in plan view. Therefore, the stress caused by the warpage suppression films 86 and 46 may locally concentrate around the recess 91, and deformation (warpage amount A) may occur in a portion of the second multilayer wiring layer 80 overlapping with the recess 91 of the second semiconductor layer 70 in plan view. The deformation of the second multilayer wiring layer 80 causes warpage or peeling of the wiring and the internal electrode pad 83 of the second multilayer wiring layer 80, and causes deterioration in reliability.

On the other hand, as illustrated in FIG. 9, in the solid-state imaging device 1A of the first embodiment, the warpage suppression films 86 and 46 have the openings 86a₁ and 46al in the overlapping regions 86a and 46a overlapping with the recess 91 of the second semiconductor layer 70 in plan view. Therefore, it is possible to alleviate a phenomenon in which the stress caused by the warpage suppression films 86 and 46 locally concentrates around the recess 91, and it is possible to suppress the deformation (warpage amount A) in the portion of the second multilayer wiring layer 80 overlapping with the recess 91 of the second semiconductor layer 70 in plan view.

Therefore, it is possible to suppress warpage or peeling occurring in the wiring of the multilayer wiring layer 80 and the internal electrode pad 83 due to local deformation of the second multilayer wiring layer 80.

Therefore, according to the solid-state imaging device 1A according to the first embodiment, it is possible to further improve reliability.

### <<Modifications of First Embodiment>>

### <Modification 1-1>

In the first embodiment described above, as illustrated in FIG. 7, a case where the planar shapes of the openings 86a₁ and 46a₁ of the warpage suppression films 86 and 46 are rectangular has been described, but the present technology is not limited to the rectangular shape.

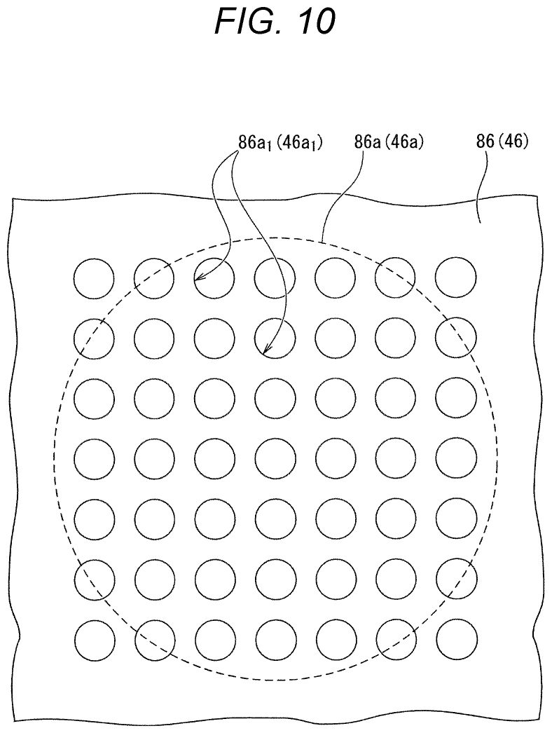

For example, as illustrated in FIG. 10, the openings 86a₁ and 46a₁ of the warpage suppression films 86 and 46 may be formed in a circular planar shape. Also in this case, effects similar to those of the first embodiment described above can be obtained.

### <Modification 1-2>

Furthermore, in the first embodiment described above, as illustrated in FIG. 7, a case has been described in which the openings 86a₁ and 46a₁ are interspersed in the overlapping regions 86a and 46a of the warpage suppression films 86 and 46. However, the present technology is not limited to the configuration in which the openings 86a₁ and 46a₁ are interspersed in the overlapping regions 86a and 46a of the warpage Suppression films 86 and 46.

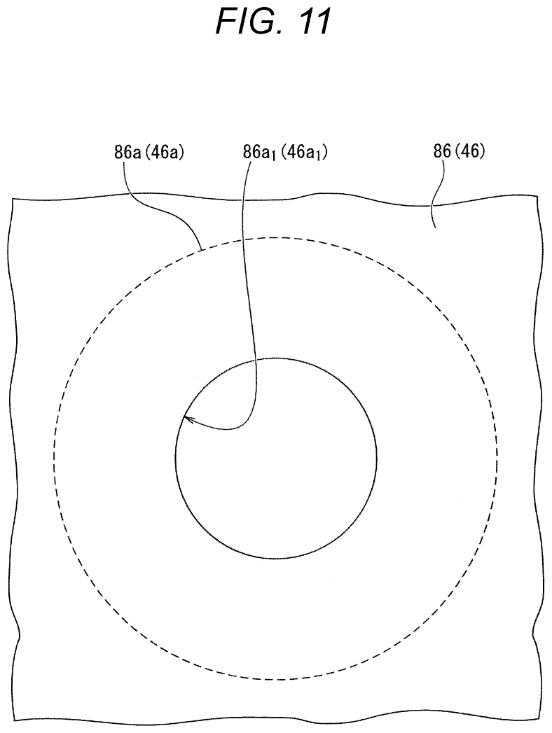

For example, as illustrated in FIG. 11, one opening 86a₁, 46a₁ may be provided in the overlapping region 86a, 46a of the warpage suppression film 86, 46. Also in this case, effects similar to those of the first embodiment described above can be obtained.

### <Modification 1-3>

In the first embodiment described above, as illustrated in FIG. 4, a case has been described in which the recess 91 is provided in the second semiconductor layer 70 overlapping with the peripheral portion 2B of the semiconductor chip 2 in plan view, and the openings 86a₁ and 46a₁ are provided in the overlapping regions 86a and 46a of the warpage suppression films 86 and 46 overlapping with the recess 91. However, the present technology is not limited to the recess 91 of the first embodiment described above.

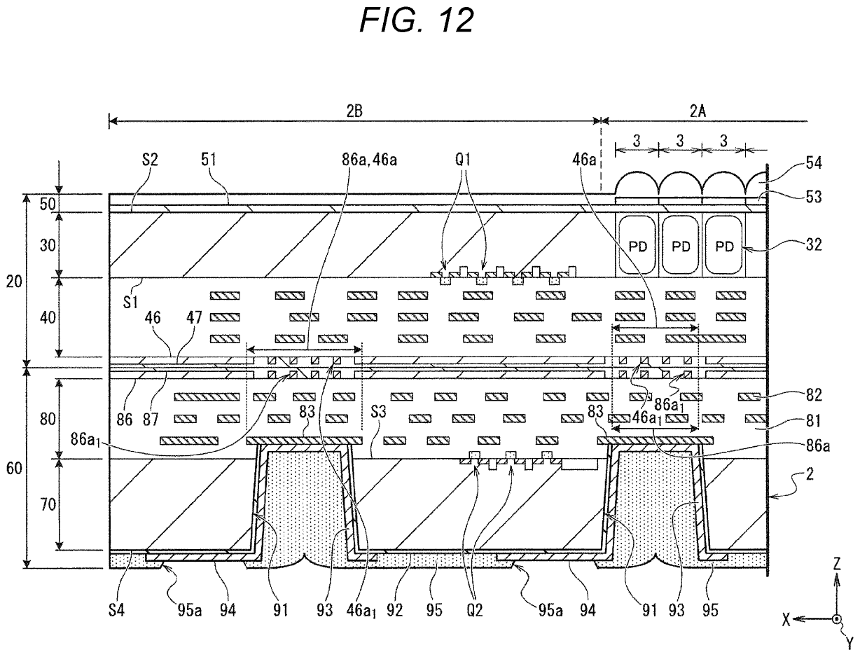

For example, as illustrated in FIG. 12, the recess 91 may be provided in the second semiconductor layer 70 overlapping with the sensor pixel array unit 2A of the semiconductor chip 2 in plan view, and the openings 86a₁ and 46a₁ may be provided in the overlapping regions 86a and 46a of the warpage suppression films 86 and 46 overlapping with the recess 91. Also in this case, effects similar to those of the first embodiment described above can be obtained.

Furthermore, since it is possible to suppress the deformation (warpage amount A) in the portion of the second multilayer wiring layer 80 overlapping with the recess 91 immediately below the sensor pixel array unit 2A in plan view, it is possible to suppress the warpage of the internal electrode pad 83. Therefore, it is possible to suppress a phenomenon in which light reflected by the internal electrode pad 83 is condensed due to the warpage of the internal electrode pad 83 and appears as a projection image, and it is possible to further improve image quality.

### <Modification 1-4>

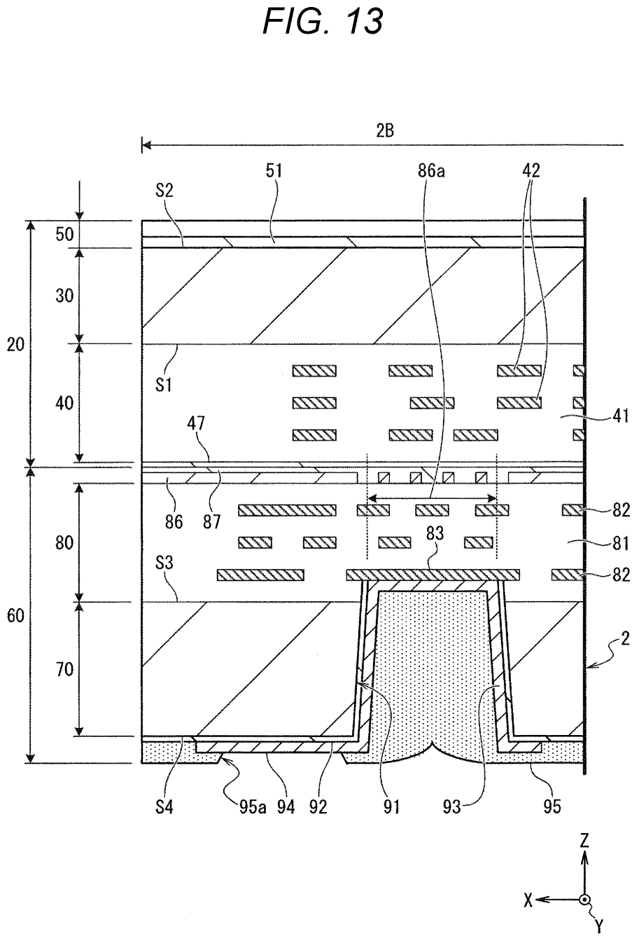

Furthermore, in the first embodiment described above, as illustrated in FIG. 6, a case where the warpage suppression films 86 and 46 are provided on both the first laminate 20 and the second laminate 60 has been described, but the present technology can also be applied to a case where the warpage suppression film is provided on at least one of the first laminate 20 or the second laminate 60. FIG. 13 illustrates a case where the warpage suppression film 86 is provided on the second laminate 60 of the first laminate 20 and the second laminate 60. Then, the opening 86a is provided in the overlapping region 86a of the warpage suppression film 86 on the second laminate 60 side.

### Second Embodiment

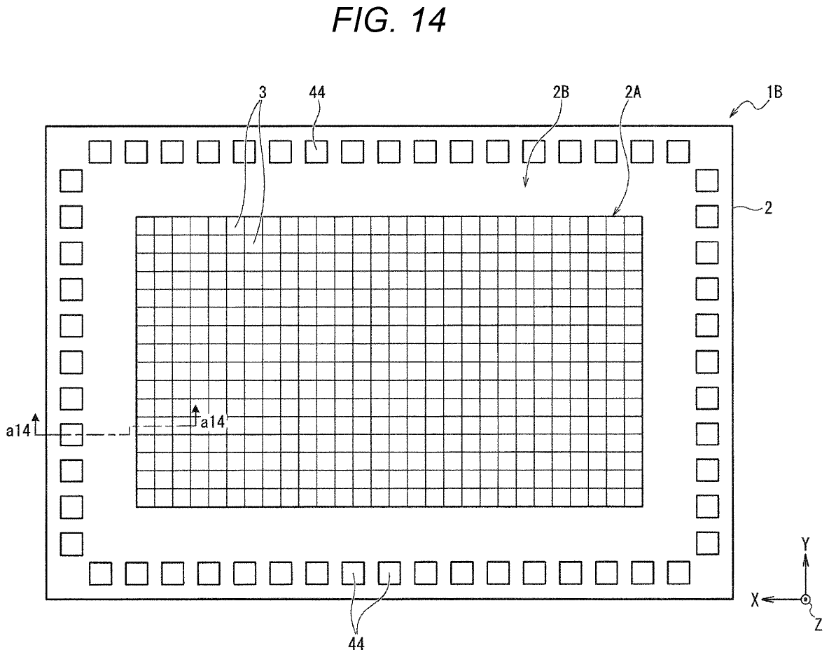

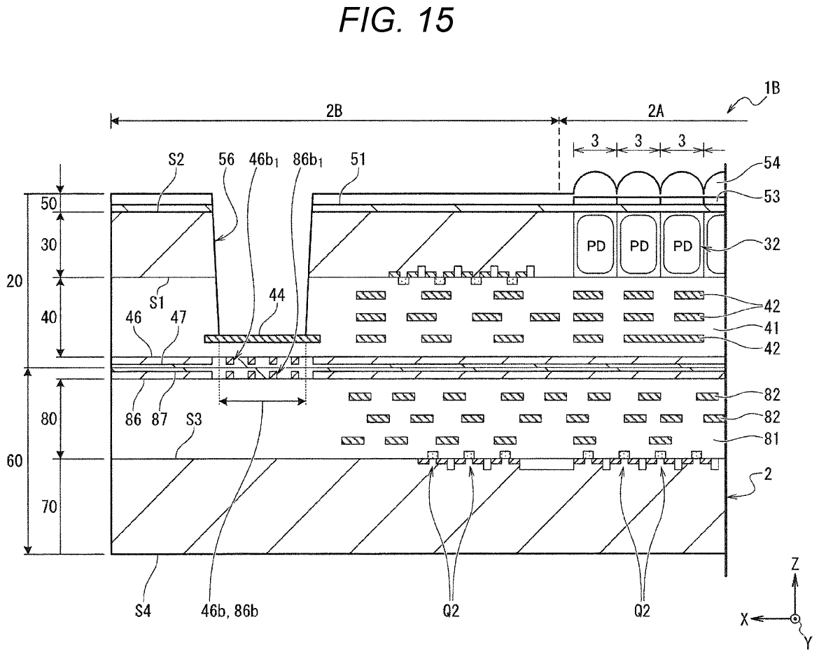

As illustrated in FIGS. 14 and 15, a solid-state imaging device 1B according to the second embodiment of the present technology basically has a configuration similar to that of the solid-state imaging device 1A according to the first embodiment described above, and is different in the configurations of the external electrode pad and the recess.

That is, as illustrated in FIG. 5, in the first embodiment described above, the recess 91 is provided in the second laminate 60 so as to overlap with the internal electrode pad 83 of the second multilayer wiring layer 80 in plan view, and the openings 86a₁ and 46a₁ are provided in the overlapping regions 86a and 46a of the warpage suppression films 86 and 46 so as to overlap with the recess 91.

On the other hand, as illustrated in FIG. 15, in the second embodiment, the recess 56 is provided in the first laminate 20 so as to overlap with the internal electrode pad 44 of the first multilayer wiring layer 40 in plan view, and openings 46b₁ and 86b₁ are provided in the overlapping regions 46b and 86b of the warpage Suppression films 46 and 86 so as to overlap with the recess 56.

As illustrated in FIG. 15, the internal electrode pad 44 is provided in, for example, the wiring layer 42, which is the third layer when counted from the first semiconductor layer 30 side of the first multilayer wiring layer 40. The internal electrode pad 44 functions as an input/output terminal for electrically connecting the semiconductor chip 2 to an external device. Then, a connection member such as a solder bump or a bonding wire is connected to the internal electrode pad 44.

The recess 56 extends from the second surface S2 side of the first semiconductor layer 30 toward the first multilayer wiring layer 40 and reaches the internal electrode pad 44 of the first multilayer wiring layer 40. That is, the recess 56 penetrates the first semiconductor layer 30 over the first surface S1 and the second surface S2 and reaches the internal electrode pad 44 of the first multilayer wiring layer 40.

The overlapping regions 46b and 86b of the warpage Suppression films 46 and 86 are, for example, lattice-shaped planar patterns including the openings 46b₁ and 86b₁, similarly to the overlapping regions 46a and 86b of the first embodiment described above.

The solid-state imaging device 1B according to the second embodiment can also produce effects similar to the effects produced by the solid-state imaging device 1A according to the first embodiment described above.

### Third Embodiment

### <<Application Examples to Electronic Apparatus>>

The present technology (technology of the present disclosure) can be applied to various electronic apparatuses such as an imaging device such as a digital still camera or a digital video camera, a mobile phone having an imaging function, or other apparatuses having an imaging function, for example.

FIG. 16 is a diagram illustrating a schematic configuration of an electronic apparatus (for example, a camera) according to a third embodiment of the present technology.

As illustrated in FIG. 16, an electronic apparatus 100 includes a solid-state imaging device 101, an optical lens 102, a shutter device 103, a drive circuit 104, and a signal processing circuit 105. The electronic apparatus 100 is an embodiment in a case where the solid-state imaging device 1A according to the first embodiment of the present technology is used as an electronic apparatus (for example, a camera) as the solid-state imaging device 101.

The optical lens 102 forms an image of image light (incident light 106) from a subject on an imaging plane of the solid-state imaging device 101. Therefore, signal charge is accumulated in the solid-state imaging device 101 over a certain period. The shutter device 103 controls a light irradiation period and a light shielding period for the solid-state imaging device 101. The drive circuit 104 supplies a drive signal for controlling a transfer operation of the solid-state imaging device 101 and a shutter operation of the shutter device 103. In accordance with a drive signal (timing signal) supplied from the drive circuit 104, the solid-state imaging device 101 performs charge transfer. The signal processing circuit 105 performs various types of signal processing on a signal (pixel signal) output from the solid-state imaging device 101. A video signal subjected to the signal processing is stored into a storage medium such as a memory, or is output to a monitor.

With such a configuration, reliability can be further improved in the solid-state imaging device 101, and thus reliability can be further improved also in the electronic apparatus 100 according to the third embodiment.

Note that the electronic apparatus 100 to which the solid-state imaging devices according to the embodiments described above can be applied is not limited to a camera, and the solid-state imaging devices can also be applied to other electronic apparatuses. For example, the solid-state imaging device may be applied to an imaging device such as a camera module for a mobile device such as a mobile phone or a tablet terminal.

Furthermore, the present technology can be applied to any photodetection device including not only the above-described solid-state imaging device as an image sensor but also a ranging sensor that is also called a time of flight (ToF) sensor and measures a distance, and the like. The ranging sensor is a sensor that emits irradiation light toward an object, detects reflected light that is the irradiation light reflected from a surface of the object, and calculates a distance to the object on the basis of a flight time from the emission of the irradiation light to reception of the reflected light. Also in this ranging sensor, the pixel transistor described above can be adopted.

Note that the present technology may have the following configurations.

(1)

A photodetection device including:
a semiconductor layer that has a first surface and a second surface located opposite to each other in a thickness direction;
a multilayer wiring layer that is provided on the first surface side of the semiconductor layer;
a warpage suppression film that is provided on a side opposite to the semiconductor layer side of the multilayer wiring layer; and
a recess that overlaps with the warpage suppression film in plan view and extends from the second surface side of the semiconductor layer to the multilayer wiring layer, in which
the warpage suppression film has an opening in an overlapping region overlapping with the recess in plan view.
   (2)

The photodetection device according to (1), in which the openings are interspersed.

(3)

The photodetection device according to (1) or (2), in which the overlapping region of the warpage suppression film is a lattice-shaped planar pattern including the opening.

(4)

The photodetection device according to any one of (1) to (3), further including:
a contact electrode that is provided in the recess and connected to a wiring layer of the multilayer wiring layer; and
an external electrode pad that is provided on the second surface side of the semiconductor layer and connected to the contact electrode.
   (5)

The photodetection device according to (4), in which
the multilayer wiring layer includes an internal electrode pad between the warpage suppression film and the recess, and
the contact electrode is connected to the internal electrode pad.
   (6)

The photodetection device according to (4), in which
the contact electrode is provided along an inner wall of the recess, and
a solder resist film is provided in the recess so as to cover the contact electrode.
   (7)

The photodetection device according to any one of (1) to (6), in which the warpage suppression film suppresses warpage of the semiconductor layer and a wiring layer.

(8)

A photodetection device including:
a first semiconductor layer that has a first surface and a second surface located opposite to each other and is provided with a photoelectric conversion unit that photoelectrically converts light incident from the second surface side;
a first multilayer wiring layer that is provided on the first surface side of the first semiconductor layer;
a second semiconductor layer that has a third surface and a fourth surface located opposite to each other and is provided with a transistor;
a second multilayer wiring layer that is provided on the third surface side of the second semiconductor layer so as to overlap with the first multilayer wiring layer;
a warpage suppression film that is provided between the first multilayer wiring layer and the second multilayer wiring layer; and
a recess that overlaps with the warpage suppression film in plan view and extends from the fourth surface side of the second semiconductor layer to the second multilayer wiring layer, in which
the warpage suppression film has an opening in an overlapping region overlapping with the recess in plan view.
   (9)

The photodetection device according to (8), in which the openings are interspersed.

(10)

The photodetection device according to (8) or (9), in which the overlapping region of the warpage suppression film is a lattice-shaped planar pattern including the opening.

(11)

The photodetection device according to (8), further including:
a contact electrode that is provided in the recess and connected to a wiring layer of the multilayer wiring layer; and
an external electrode pad that is provided on the second surface side of the semiconductor layer and connected to the contact electrode.
   (12)

The photodetection device according to (11), in which
the second multilayer wiring layer includes an internal electrode pad between the warpage suppression film and the recess, and
the contact electrode is connected to the internal electrode pad.
   (13)

The photodetection device according to (11), in which
the contact electrode is provided along an inner wall of the recess, and
a solder resist film is provided in the recess so as to cover the contact electrode.
   (14)

The photodetection device according to any one of (8) to (12), in which the warpage suppression film suppresses warpage of the semiconductor layer and a wiring layer.

(15)

An electronic apparatus including:
a photodetection device;
an optical lens that forms an image of image light from a subject on an imaging surface of the photodetection device; and
a signal processing circuit that performs signal processing on a signal output from the photodetection device, in which
the photodetection device includes
a semiconductor layer that has a first surface and a second surface located opposite to each other in a thickness direction,
a multilayer wiring layer that is provided on the first surface side of the semiconductor layer,
a warpage suppression film that is provided on a side opposite to the semiconductor layer side of the multilayer wiring layer, and
a recess that overlaps with the warpage suppression film in plan view and extends from the second surface side of the semiconductor layer to the multilayer wiring layer, and
the warpage suppression film has an opening in an overlapping region overlapping with the recess in plan view.

The scope of the present technology is not limited to the exemplary embodiments illustrated in the drawings and described above, but includes also all embodiments that produce effects equivalent to the effects that the present technology intends to produce. Moreover, the scope of the present technology is not limited to the combinations of the features of the invention defined by the claims, and may be defined by any desired combination of specific features among all the disclosed features.

### REFERENCE SIGNS LIST

1A Solid-state imaging device
2 Semiconductor chip
2A Sensor pixel array unit
2B Peripheral portion
3 Sensor pixel
4 Vertical drive circuit
5 Column signal processing circuit
6 Horizontal drive circuit
7 Output circuit
8 Control circuit
10 Pixel drive line
11 Vertical signal line
12 Horizontal signal line
13 Logic circuit
15 Pixel circuit
20 First laminate
30 First semiconductor layer
32 Photoelectric conversion region
34 Photoelectric conversion unit
40 First multilayer wiring layer
41 Interlayer insulating film
42 Wiring layer
44 Internal electrode pad
46 Warpage suppression film
46a, 46b Overlapping region
46a₁, 46b₁ Opening
47 Bonding layer
50 Light condensing layer
51 Planarization film
53 Optical filter
54 On-chip lens
56 Recess
60 Second laminate
70 Second semiconductor layer
80 Second multilayer wiring layer
81 Interlayer insulating film
82 Wiring layer
83 Internal electrode pad
86 Warpage suppression film
86a, 86b Overlapping region
86a₁, 86b₁ Opening
87 Bonding layer
91 Recess
92 Isolation insulating film
93 Contact electrode
94 External electrode pad
95 Solder resist film
100 Electronic apparatus
101 Solid-state imaging device
102 Optical system (optical lens)
103 Shutter device
104 Drive circuit
105 Signal processing circuit
S1 First surface
S2 Second surface
S3 Third surface
S4 Fourth surface
Q1, Q2 Transistor

What is claimed is:

1. A photodetection device comprising:
a semiconductor layer that has a first surface and a second surface located opposite to each other in a thickness direction;
a multilayer wiring layer that is provided on the first surface side of the semiconductor layer;
a warpage suppression film that is provided on a side opposite to the semiconductor layer side of the multilayer wiring layer; and
a recess that overlaps with the warpage suppression film in plan view and extends from the second surface side of the semiconductor layer to the multilayer wiring layer, wherein
the warpage suppression film has an opening in an overlapping region overlapping with the recess in plan view.

2. The photodetection device according to claim 1, wherein the openings are interspersed.

3. The photodetection device according to claim 1, wherein the overlapping region of the warpage suppression film is a lattice-shaped planar pattern including the opening.

4. The photodetection device according to claim 1, further comprising:
a contact electrode that is provided in the recess and connected to a wiring layer of the multilayer wiring layer; and
an external electrode pad that is provided on the second surface side of the semiconductor layer and connected to the contact electrode.

5. The photodetection device according to claim 4, wherein
the multilayer wiring layer includes an internal electrode pad between the warpage suppression film and the recess, and
the contact electrode is connected to the internal electrode pad.

6. The photodetection device according to claim 4, wherein
the contact electrode is provided along an inner wall of the recess, and
a solder resist film is provided in the recess so as to cover the contact electrode.

7. The photodetection device according to claim 1, wherein the warpage suppression film suppresses warpage of the semiconductor layer and a wiring layer.

8. A photodetection device comprising:
a first semiconductor layer that has a first surface and a second surface located opposite to each other and is provided with a photoelectric conversion unit that photoelectrically converts light incident from the second surface side;
a first multilayer wiring layer that is provided on the first surface side of the first semiconductor layer;
a second semiconductor layer that has a third surface and a fourth surface located opposite to each other and is provided with a transistor;
a second multilayer wiring layer that is provided on the third surface side of the second semiconductor layer so as to overlap with the first multilayer wiring layer;
a warpage suppression film that is provided between the first multilayer wiring layer and the second multilayer wiring layer; and
a recess that overlaps with the warpage suppression film in plan view and extends from the fourth surface side of the second semiconductor layer to the second multilayer wiring layer, wherein
the warpage suppression film has an opening in an overlapping region overlapping with the recess in plan view.

9. The photodetection device according to claim 8, wherein the openings are interspersed.

10. The photodetection device according to claim 8, wherein the overlapping region of the warpage suppression film is a lattice-shaped planar pattern including the opening.

11. The photodetection device according to claim 8, further comprising:
a contact electrode that is provided in the recess and connected to a wiring layer of the multilayer wiring layer; and
an external electrode pad that is provided on the second surface side of the semiconductor layer and connected to the contact electrode.

12. The photodetection device according to claim 11, wherein
the second multilayer wiring layer includes an internal electrode pad between the warpage suppression film and the recess, and
the contact electrode is connected to the internal electrode pad.

13. The photodetection device according to claim 11, wherein
the contact electrode is provided along an inner wall of the recess, and
a solder resist film is provided in the recess so as to cover the contact electrode.

14. The photodetection device according to claim 8, wherein the warpage suppression film suppresses warpage of the semiconductor layer and a wiring layer.

15. An electronic apparatus comprising:
a photodetection device;
an optical lens that forms an image of image light from a subject on an imaging surface of the photodetection device; and
a signal processing circuit that performs signal processing on a signal output from the photodetection device, wherein
the photodetection device includes
a semiconductor layer that has a first surface and a second surface located opposite to each other in a thickness direction,
a multilayer wiring layer that is provided on the first surface side of the semiconductor layer,
a warpage suppression film that is provided on a side opposite to the semiconductor layer side of the multilayer wiring layer, and
a recess that overlaps with the warpage suppression film in plan view and extends from the second surface side of the semiconductor layer to the multilayer wiring layer, and
the warpage suppression film has an opening in an overlapping region overlapping with the recess in plan view.
